(19) United States
(12) Patent Application Publication
(10) Pub. No.: US 2024/0246828 A1
(43) Pub. Date: Jul. 25, 2024

(54) PROCESS FOR PRODUCING A SILICON COMPOSITE

(71) Applicant: WACKER CHEMIE AG, München (DE)

(72) Inventors: Alena Kalyakina, München (DE); Christoph Dräger, München (DE); Jan Tillmann, München (DE)

(73) Assignee: WACKER CHEMIE AG, München (DE)

(21) Appl. No.: 18/562,423

(22) PCT Filed: Dec. 20, 2022
(86) PCT No.: PCT/EP2022/087133

§ 371 Date: Nov. 20, 2023

(30) Foreign Application Priority Data
Dec. 20, 2021 (WO) PCT/EP2021/086900

(51) Int. Cl. C01B 33/027

(52) U.S. Cl. CPC C01B 33/027

(57) ABSTRACT

The Applicants respectfully request that the abstract of the instant application be removed in its entirety and replaced with the following wording.
A process for producing a silicon composite. Where the process includes thermal decomposition of at least one silicon precursor in the presence of an amount of porous particles.

The present invention relates to a process for producing a silicon composite by thermal decomposition of at least one Si precursor in the presence of porous particles, wherein silicon is deposited in pores and on the surface of the porous particles and the silicon composite has a target content of silicon of 35% to 60% by weight.

As storage media for electric current, lithium-ion batteries (LIB) are currently the most practical electrochemical energy storage means having the highest energy densities. LIB are used especially in the field of portable electronics, for tools and also for electrically propelled means of transport, such as bicycles, scooters or automobiles. Graphitic carbon is widely used as the active material for negative electrodes (anodes). A disadvantage is the relatively low electrochemical capacity of such carbons, which is theoretically at most 372 mAh per gram of graphite, and corresponds to only about one tenth of the electrochemical capacity theoretically achievable with lithium metal. Alternative active materials for the anode use a silicon addition, as described for example in EP 1730800 B1 or EP 3335262 B1. Silicon forms binary electrochemically active alloys with lithium which allow very high electrochemically achievable lithium contents of up to 3579 mAh per gram of silicon.

The intercalation and deintercalation of Li ions in silicon has the disadvantage that it is accompanied by a very high volume change, which may be up to 300% in the case of complete intercalation. These volume changes subject the silicon-containing active material to severe mechanical stress, as a result of which the active material may break apart. This process, also referred to as electrochemical grinding, leads to a loss of electrical contacting in the active material and in the electrode structure and thus to irreversible loss of capacity of the electrode.

Furthermore, the surface of the Si-containing active material can react with constituents of the electrolyte to form passivating protective layers (Solid Electrolyte Interphase; SEI). The components formed are no longer electrochemically active. The lithium bound therein is no longer available to the system, thus leading to a pronounced capacity loss of the LIB. Due to volume change of the silicon during the charging/discharging process of the LIB, the SEI regularly ruptures, thus uncovering further free surfaces of the Si-containing active material which are then exposed to further SEI formation. Since in a LIB the amount of mobile lithium, which corresponds to the usable capacity, is limited by the cathode material it is increasingly consumed and the capacity decreases after just a few cycles.

Known active materials for anodes of LIB include Si—C composite particles in which silicon from gaseous or liquid precursors is intercalated into porous C particles. The advantage of Si—C composites is that the silicon is finely distributed and embedded in a carbon framework which tolerates the volume changes of the silicon and simultaneously maintains the electrical contacting of the silicon. Such Si—C composites are produced for example by gas phase deposition of one or more Si precursors in pores of porous carbon matrices. The introduction of silicon into porous structures is also known as chemical vapor infiltration (CVI).

If Si composites are produced by CVI the Si precursor is usually employed at low absolute and partial pressure and thus at low concentration, thus necessitating long reaction times to achieve high Si proportions in the silicon-containing material since thick Si layers, also known as coarse silicon, are otherwise formed on the particle exterior. These thick Si layers are harmful in that in contact with electrolyte and in the course of cycling they lead to heavy structuring of the particle surface in combination with constant reforming of the SEI. In addition, optimal adjustment of the process parameters requires precise knowledge of all reaction parameters which must usually be determined empirically. In addition, the employed porous matrices show a certain variation range in respect of their pore and particle size distribution, thus making it very challenging to avoid overinfiltration that leads to thick Si layers. Thick Si layers are also formed if, for reasons of productivity, the infiltration is carried out continuously at relatively high concentration of the silicon precursor (Si precursor) and/or relatively high temperature.

WO 2022/029422 A1 discloses a Si—C composite produced by CVI that comprises 25 to 65% by weight of silicon. The composite consists of a meso- and microporous C scaffold that comprises a multiplicity of domains of nanoscale elemental silicon inside the pores and on its surface. It may be produced from the porous C particles and silane in a fluidized bed reactor at a temperature of 450° C. and reduced pressure. To prevent formation of thick Si layers (coarse bulk silicon), silane concentrations of less than 20% by volume were employed throughout. This high dilution necessarily results in long reaction times and a high consumption of inert gas, thus reducing the economy of the process.

Against this backdrop it is an object of the present invention to provide a process for producing a silicon-containing material which upon use as active material in anodes of LIB ensures a high cycle stability while being obtainable more quickly and thus more economically than allowed by known production processes. The formation of thick silicon layers should therefore be avoided.

The present invention relates to a process for producing a silicon composite by thermal decomposition of at least one Si precursor in the presence of porous particles, wherein silicon is deposited in pores and on the surface of the porous particles and the silicon composite has a target content of Si of 35% to 60% by weight, wherein in regular operation the process is performed at
an average temperature T of 300° C. to 500° C. and
a concentration C of the Si precursor of 30% to 100% by volume in the supplied gas stream.

The process comprises at least one stage A in which a change Δ in at least one of the parameters T and C relative to regular operation and optionally relative to a further stage A is effected, wherein

$$Δ T = 10 ° C . to 130 ° C . and$$

$$Δ C = 2 \% to 70 \% by volume ,$$

with the proviso that during stage A 0.1% to 50% of the recited target content of silicon is deposited or that during two or more stages A altogether at most 50% of the recited target content is deposited.

The present invention further provides for a further process substantially corresponding to the above-described process, wherein in regular operation the further process is performed at
an average temperature T of 300° C. to 500° C.,
a concentration C of the Si precursor of 30% to 100% by volume and
a volume flow VS of the Si precursor of 0.01 to 20 NL/h, based on 1 g of the porous particles.

The further process likewise comprises at least one stage A in which a change Δ in at least one of the parameters T, C and VS relative to regular operation and optionally relative to a further stage A is effected, wherein

$$Δ T = 10 ° C . to 130 ° C . ,$$

$$Δ C = 2 \% to 70 \% by volume and$$

$$Δ VS = 0.01 to NL / h ,$$

with the proviso that during stage A 0.1% to 50% of the recited target content of silicon is deposited or that during two or more stages A altogether at most 50% of the recited target content is deposited.

One advantage of the process according to the invention is that the conversion of the Si precursor during the entire process duration is more than 30%. This is additionally followed by a particularly uniform deposition of silicon on and especially in the porous particles, thus resulting in a high stability of the resulting silicon composite in the application as active material in anodes for LIB.

Dividing the infiltration reaction into phases having different process parameters allows targeted shortening of the overall process duration coupled with high product performance. It has surprisingly been found that under static conditions the conversion of the supplied Si precursor does not remain constant but rather changes in the course of the reaction duration, with the result that static process modes do not achieve optimal utilization of the Si precursors. This is compensated by the adapted process mode of the deposition reaction, thus increasing conversion.

In addition, the process according to the invention surprisingly overcomes the disadvantageous formation of thick Si layers, with the result that the Si composites obtained by the process have a high electrochemical performance.

In regular operation the supplied volume flow VS of the Si precursor into the reactor may be 0.01 to 10 NL/h, preferably 0.01 to 5 NL/h, per gram of the employed porous particles. Determination of the volume flow may be effected by commonly used methods, such as via a rotameter.

ΔVS may be 0.01 to 5 NL/h, preferably 0.01 to 2 NL/h, per gram of the employed porous particles.

The silicon composite may have a target content of silicon (obtained by deposition from the Si precursor) of 40% to 55% by weight, preferably of 42% to 50% by weight, based on the total weight of the silicon composite.

The target content of Si may be empirically determined by repeated sampling during the process.

It is preferable when the target content of Si is determined during the process by analysis of the composition of an offgas stream with at least one method selected from the group comprising gas chromatography, mass spectrometry, infrared spectroscopy and thermal conductivity measurement.

Determination of the target content of Si is particularly preferably carried out by continuous analysis of the offgas composition by gas chromatography or thermal conductivity measurement. The offgas flow may be withdrawn directly at the reactor outlet for analysis of the gas composition. Determination of the deposited silicon may also be effected indirectly by quantification of the hydrogen present in the offgas provided no hydrogen was used for silane dilution.

The average temperature T may be 315° C. to 475° C. in regular operation, preferably 330° C. to 450° C.

The average temperature in regular operation T_{R} is defined as the average of all temperatures in regular operation. Temperature is to be understood as meaning the temperature in a process by means of which the process is controlled. If the temperature in stage A is changed by ΔT without interrupting the feed of the Si precursor, a heating phase or cooling phase is considered part of stage A. The average temperature of stage A (T_{A}) is then used.

ΔT may be 20° C. to 100° C., preferably 20° C. to 50° C.

In regular operation the concentration C may be 30% to 100% by volume, preferably 50% to 100% by volume.

The values for C preferably relate to the concentration of the Si precursor in the reaction gas, i.e. generally to its concentration in a feed conduit of the reaction gas into a reactor. The reaction gas typically comprises the Si precursor and/or an inert gas such as nitrogen. The concentration of the Si precursor in the supplied reaction gas may be adjusted via suitable metering apparatuses such as rotameters.

ΔC may be 5% to 60% by volume, preferably 10% to 50% by volume.

It is preferable when the change Δ in at least one of the parameters C, T and VS is carried out continuously from commencement of stage A until termination thereof. In specific embodiments the change may also be carried out stepwise.

Depending on the determined target content of Si the change Δ may be commenced or terminated. In other words stage A may be commenced (deviation from regular operation) or terminated (return to regular operation) according to the change Δ.

It is preferable when the process is performed at a pressure of less than 0.7 MPa. In particular the pressure remains substantially constant during the process. Substantially means here that the pressure may have a variation range of +0.1 MPa.

The production of the Si composite particles according to the invention can be carried out in any reactors commonly used for Si infiltration. Preference is given to reactors selected from fluidized bed reactors, retort ovens, tube reactors, rotary kilns, which may be oriented in any arrangement from horizontal to vertical, and fixed-bed reactors, which may be operated as open or closed systems, for example as pressure reactors. Particular preference is given to reactors which allow homogeneous mixing of the porous particles and the silicon-containing material formed during the infiltration (only the finished end product is to be described as silicon composite) with the Si precursors. This is advantageous for the most homogeneous possible deposition of silicon in pores and on the surface of the porous particles. The reactors to which greatest preference is given are fluidized bed reactors, rotary kilns, pressure reactors, bed reactors.

It is preferable when the process according to the invention is performed in a reactor fitted with a close-clearance stirrer.

The process may further be performed in a cascade reactor system comprising two or more reactors.

Performing the process in a cascade reactor system can have the advantage over performing the process in only one reactor that long cooling and heating phases of a reactor are reduced. This may result in an economic advantage. A cascade reactor system can additionally provide the advantage that the individual reactors may be configured precisely for their purpose. A cascade reactor system is normally more scalable since varying amounts of reactors may be combined with one another to form individual phases. The adaptations to the temperatures, volume flows and concentrations may also be carried out by performing stage A and regular operation in different reactors in the reactor cascade.

The process according to the invention may comprise at least three phases:
Phase 1: Filling a reactor A with porous particles and pre-treating the particles with subsequent transferring of the pre-treated particles into a reactor B or into a reservoir vessel or the material remains in reactor A.
Phase 2: Traversing a reactor B with a gas comprising the Si precursor and typically an inert gas. A Si-free precursor may also be present; temperature-controlling the reactor to a temperature at which thermal decomposition of the Si precursor occurs on the surface and in the pores of the porous particles. Establishing a process profile which in addition to regular operation comprises at least one stage A in which at least one of the parameters T, C and VS is changed. The reaction may be carried out both at negative pressure and at positive pressure. After introduction of the silicon into and onto the pores of the porous particles the Si composite is transferred into a reactor C or for intermediate storage into a reservoir vessel or the material remains in reactor B.
Phase 3: After-treatment of the Si composite for functionalization and/or coating of the surface of the silicon-containing particles. Cooling of the particles to a defined temperature and withdrawal of Si composite from reactor C and preferably direct transfer into a storage container or direct filling into a suitable container.

In phase 1 porous particles are filled into a heatable and/or vacuum-resistant and/or pressure-resistant reactor A. This filling may be carried out manually or automatically.

The filling of reactor A with porous particles may be performed in an inert gas atmosphere or preferably ambient air. Employable inert gases include hydrogen, helium, neon, argon, krypton, xenon, nitrogen, carbon dioxide or mixtures thereof, such as forming gas. Argon or nitrogen are preferred.

Automatic filling may be carried out by means of a metering screw, rotary star valve, vibratory conveyor, plate-type metering device, belt-type metering device, vacuum metering system, negative weighing or any other metering systems for example from a silo or any other container system.

The objective of the pre-treating of the particles in reactor A in phase 1 is to remove air/oxygen, water or dispersing agents, such surfactants or alcohols, and impurities from the particles. This can be achieved by inertizing with inert gas (cf. preceding stage), increasing the temperature to up to 1000° C., reducing the pressure to up to 1 Pa or combining the individual process steps.

The objective of the pre-treating in phase 1 may further be to alter the chemical surface constitution of the porous particles with further substances. The adding may be carried out before or after the drying and a further heating step may be carried out before the material is transferred into reactor B. The substances may be added to the reactor in gaseous, solid or liquid form or in the form of a solution. Mixtures, emulsions, suspensions, aerosols or foams are also possible. Possible substances include carbon dioxide, water, sodium hydroxide solution, potassium hydroxide solution, hydrofluoric acid, phosphoric acid, nitric acid, hydrochloric acid, ammonia, ammonium hydrogenphosphate, lithium nitrate, sodium nitrate, potassium nitrate, lithium chloride, sodium chloride, potassium chloride, lithium bromide, sodium bromide, potassium bromide, alkoxides.

The transferring of the porous particles into a further reactor or container may be effected via a downpipe, continuous conveyor, flow conveyor/suction or pressure conveying apparatus (for example vacuum conveyor, transport blower); mechanical conveyors (for example powered roller conveyors, screw conveyors, hanging conveyors, over/under conveyors, bucket conveyors, rotary star valves, chain conveyors, scraper conveyors, conveyor belts, vibratory conveyors); gravity conveyors (for example chutes, roller tracks, ball tracks, rail tracks).

In phase 2 the pre-treated material is heated to an average temperature of 300° C. to 500° C., particularly preferably 315° C. to 475° C. and especially preferably 330° C. to 450° C. in reactor B.

During the changing of the temperature or upon achieving the temperature or during the running of a temperature profile reactor B may be alternately or simultaneously traversed by a gas consisting of at least one inert gas and/or at least one reactive component consisting of at least one Si precursor and/or at least one Si-free precursor. Different compositions of the gas are possible in succession or may be varied within the parameters of the specified composition during phase 2.

Preferred Si-free precursors (precursors containing no Si precursor) are one or more hydrocarbons. Carbon may generally be deposited in the pores and on the surface of the porous particles through thermal decomposition of the hydrocarbons.

The Si-free precursors preferably contain no further component or one or more inert gases and/or one or more reactive components, such as hydrogen, and/or one or more dopants. Dopants may include compounds containing boron, nitrogen, phosphorus, arsenic, germanium, iron or nickel. The dopants are preferably selected from the group comprising ammonia, diborane, phosphane, germane, arsane and nickel tetracarbonyl.

The metered addition of the reaction gas may be continuous or intermittent. The metered addition rate may be varied during the reaction duration.

Temperature, pressure, pressure changes or differential pressure measurements and gas flow measurements in reactor B are determinable with commonly used measuring instruments and methods of measurement. After typical calibration, different measuring instruments usually give the same measured results.

Over the total duration of the thermal decomposition reactor B may be traversed with an amount of Si precursors such that in respect of the weighed-in amount of porous particles an amount of silicon sufficient for the target capacity of the Si composite to be produced is deposited.

The heating of reactor B in phase 2 may be carried out at a constant heating rate or at a plurality of different heating rates. Heating rates may be adapted according to the configuration of the process, for example according to the size of the reactor, the amount of the porous particles in the reactor, the stirring technology or the planned reaction time.

The heating of reactor B in phase 2 may be carried out with heating rates of 1° C. to 100° C. per minute, preferably from 2° C. to 50° C. per minute.

The temperature at which the decomposition of the Si precursor commences may depend on the employed porous particles, the employed Si precursors and the other boundary conditions of the decomposition, such as the partial pressure of the Si precursor at the juncture of decomposition and the presence of other reactive components, such as catalysts, affecting the decomposition reaction.

During the decomposition of the Si precursors in phase 2 the temperature may be kept constant or else varied. The objective is the largely complete conversion of the Si precursor during the contact time of the gas with the stirred bed to produce a Si composite suitable for the application.

The target temperature for SiH₄ may be 300° C. to 500° C., preferably 315° C. to 475° C., particularly preferably 330° C. to 450° C. The target temperature for HSiCl₃ may be 380° C. to 1000° C., preferably 420° C. to 600° C. The target temperature for H₂SiCl₂ may be 350° C. to 800° C., preferably 380° C. to 500° C.

Si-free precursors such as C precursors may be employed in phase 2 in addition to Si precursors. This may be done as a mixture with Si precursors, consecutively or alternatingly. The objective is targeted functionalization of the freshly formed silicon surface.

The gas phase from phase 2 may consist of an inert gas and/or at least one reactive component containing an Si and/or at least one Si-free precursor in potentially varying composition. The one or more Si precursors may generally be introduced into reactor B in mixed form or separately or in admixture with inert gas constituents or as pure substances.

In phase 2 the bed consisting of porous particles is preferably continuously recirculated. The recirculation may be effected via one or more stirring means or by a rotating motion of the reactor itself (for example intensive mixers from Maschinenfabrik Gustav Eirich) or combinations thereof. The state of motion of the moving bed is characterized by Froude numbers between 1 and 10. The Froude number is preferably between 1 and 6, particularly preferably between 1 and 4.

The thermal decomposition of the Si precursors in the presence of the porous particles is preferably carried out at 0.05 MPa to 5 MPa, particularly preferably at 0.08 to 0.7 MPa.

The progress of the reaction in phase 2 is preferably analytically monitored to detect the end of the reaction and thus to keep the reactor occupancy time as short as possible. Processes for observing the progress of the reaction comprise for example temperature measurement for determining exo- or endothermicity to determine the progress of the reaction through changing ratios of solid to gaseous reactor content constituents and further methods which allow monitoring of the changing composition of the gas space during the reaction. In a preferred variant of the process the composition of the gas phase is determined by a gas chromatograph and/or thermal conductivity detector and/or an infrared spectrometer and/or a Raman spectrometer and/or a mass spectrometer. In a preferred embodiment the water content is determined using a thermal conductivity detector and/or optionally the presence of any chlorosilanes is determined using a gas chromatograph or gas infrared spectrometer.

In a further preferred variant of the process the reactor B/the position of the gas outlet is fitted with a technical solution for removing any condensable or re-sublimable byproducts occurring. In a particularly preferred variant silicon tetrachloride is condensed and separately removed from the Si composite.

In phase 3 of the process the Si-containing particles in reactor C are after-treated and/or deactivated and/or coated. To this end reactor C is preferably purged with oxygen, in particular with a mixture of inert gas and oxygen. This allows the surface of the Si composite to be modified and/or functionalized and/or deactivated. For example it is possible to effect a reaction of any reactive groups present on the surface of the Si composite. It is preferable to employ to this end a mixture of nitrogen, oxygen and optionally alcohols and/or water which preferably contains at most 20% by volume, particularly preferably at most 10% by volume and especially preferably at most 5% by volume of oxygen and preferably at most 100% by volume, particularly preferably at most 10% by volume and especially preferably at most 1% by volume of water. This step is preferably carried out at temperatures of at most 250° C., particularly preferably at most 100° C. and especially preferably at most 50° C. The deactivation of the particle surfaces may also be effected with a gas mixture containing inert gas and alcohols. It is preferable to employ nitrogen and isopropanol here. However, it is also possible to employ methanol, ethanol, butanols, pentanol or longer-chain and branched alcohols and diols.

Deactivation of the particles may also be effected by dispersion in a liquid solvent or a solvent mixture. This may contain isopropanol or an aqueous solution. The deactivation of the particles in phase 3 may also be carried out by a coating using C—, Al— and B-containing precursors at temperatures of 200-800° C. and optional subsequent treatment with oxygen-containing atmosphere.

Employable aluminum-containing precursors include trimethylaluminum ((CH₃)₃Al), aluminum 2,2,6,6-tetramethyl-3,5-heptanedionate (AI(OCC(CH₃)₃CHCOC(CH₃)₃)₃), tris(dimethylamido)aluminum (AI(N(CH₃)₂)₃) and aluminum triisopropanolate (C₉H₂₁AIO₃).

Employable boron-containing precursors include borane (BH₃), triisopropyl borate ([(CH₃)₂CHO]₃B), triphenylborane ((C₆H₅)₃B) and tris(pentafluorophenyl)borane (C₆F₅)₃B.

In phase 3 after-coatings of the particles with solid-state electrolytes may also be introduced by a thermal decomposition of for example tert-butyllithium and trimethyl phosphate.

In phase 3, the Si-composites may in principle be withdrawn from reactor C, optionally while retaining an inert gas atmosphere present in reactor C. This may be done via the following discharging methods: pneumatically (via super- or sub-atmospheric pressure); mechanically (rotary star valve, plate-type discharging device, discharging screw/stirring means in the reactor, belt-type discharging device), gravimetrically (double-flap valve/ball valve, optionally vibration-assisted).

When using hydrocarbons in phase 3 and/or in addition to the Si infiltration during phase 2 as further Si-free pecursors the target temperatures employed are those at which decomposition of the hydrocarbons commences and carbon is deposited in pores and on the surface of the porous particles. It is preferable when the target temperatures selected in this embodiment are in the range from 250° C. to 1000° C., particularly preferably from 350° C. 850° C. and most preferably from 400° C. to 650° C.

Technical requirements of the reactors and optional particulars for specific variants of the invention:

### Reactor A:

The reactor is at least temperature-controllable.
The reactor may be vacuum-resistant.
system for pre-heating, drying and inertizing the porous particles.
a system for targeted addition/metered addition of the porous particles may be connected.
drying/removing impurities from the porous particles may be achieved by connecting a system which makes it possible to remove condensable or re-sublimable substances.
It is possible to connect a system with which the porous particles may be transferred into the reactor B.

### Reactor B:

The reactor is at least temperature-controllable.
Contains a stirrer means according to the invention
System for metered addition of reaction gas
System for discharging of reaction gas
To simplify the process a hydrogen separator may be connected.
To remove condensable or re-sublimable byproducts occurring in the gaseous reaction products it is possible to connect a container which allows removal of the byproducts by condensation or re-sublimation.
It is possible to connect a system with which the material may be transferred into the reactor C or a reservoir vessel.

### Reactor C:

The reactor is at least temperature-controllable.
System for removal of condensable or re-sublimable byproducts.
It is possible to connect a container which allows removal of the byproducts by condensation or re-sublimation.
System for metered addition of reaction gas for functionalization
System for discharging of reaction gas
It is possible to connect a system with which the material may be transferred into a reservoir vessel.

A reactor may be simultaneously temperature-controllable, pressure resistant and vacuum resistant; all combinations are possible. However, it is also possible for a respective reactor to fulfill only one of the abovementioned features.

A temperature-controllable reactor is generally a reactor operable such that the temperature in the interior may be adjusted in the range between −40° C. and 1000° C. Smaller temperature ranges are possible.

It is preferable when reactor A, B and C are the same vessel, in other words the process may also be performed in only one reactor. It is in principle not excluded for reactor A, B and C to be the same vessel.

It may be provided that the process in regular operation and the at least one stage A are performed in one reactor. In a specific embodiment regular operation and stage A may be performed in separate reactors.

The porous particles and the resulting Si composite may during the process generally be in the form of a stationary bed or in the form of a moving bed through mixing. Mixing to afford a moving bed of the porous particles/of the resulting Si composite in reactor A, B and C is preferred. However, during thermal decomposition of the Si precursor in phase 2 the particles must generally be mixed. This makes it possible to ensure homogeneous contact of all porous particles with the reaction gas or homogeneous temperature distribution of the bed. Recirculation of the particles may be effected through stirring internals in the reactor or motion of the entire reactor around a stirrer.

A further preferred configuration of reactors A, B and C are fixed reactors with moving stirring means for recirculation. The objective of the recirculation is to contact the porous solid with the reaction gas as uniformly as possible. Preferred geometries therefor are cylindrical reactors, conical reactors, spherical or polyhedral rotationally symmetric reactors or combinations thereof. The motion of the stirring means is preferably a rotational motion. For vertically operated reactors A, B and C preference is given to configurations where one stirring means or two or more stirring means mix the bed material via a rotational motion via a main stirrer shaft for example. A further configuration for a vertically operated reactor A, B or C is characterized by the utilization of a conveying screw. For horizontally operated reactors A, B or C preference is given to configurations where one stirring means or two or more stirring means mix the bed material via a rotational motion via a main stirrer shaft for example. For vertically operated reactors A, B or C preference is given to stirring means selected from the group containing helical stirrers, spiral stirrers, anchor stirrers or generally stirring means which convey the bed material axially or radially or both axially and radially. Wall clearance can be reduced by additional scrapers on the stirring means. In addition to the moving stirring means the reactor A, B or C may also have rigid internals, such as baffles.

Materials suitable for the construction of reactor A, B or C in principle include any material which exhibits the necessary mechanical strength and resistance under the respective process conditions In terms of chemical resistance the reactor A, B or C may consist both of appropriate solid materials and of chemically non-resistant (pressure-bearing) materials with special coatings or platings of media-contacting parts.

A cascade reactor system is a linked system of at least two reactors. There is no upper limit to the number of reactors. The number of reactors A, B and C relative to one another, as well as their sizes, shapes, materials and configurations may differ. The reactors may be directly connected to one another or be spatially separated from one another with feeding occurring via movable reservoir vessels. It is also conceivable for two or more reactors B to be connected to one another and for each reaction step to be carried out in a separate reactor B.

Si precursors and Si-free precursors are preferably gaseous, liquid, solid (for example sublimable), or a composition of matter optionally consisting of substances in different states of matter. In one variant of the process the Si precursors are fed directly into the bulk of porous particles in the reactor, for example from below or from the side or via a specific stirrer.

The Si precursor is preferably selected from the group comprising silicon-hydrogen compounds such as monosilane (SiH₄), disilane (Si₂H₆) and higher linear, branched or cyclic homologs, neopentasilane (Si₅H₁₂), cyclohexasilane (Si₆H₁₂), chlorine-containing silanes, such as trichlorosilane (HSiCl₃), dichlorosilane (H₂SiCl₂), chlorosilane (H₃SiCI), tetrachlorosilane (SiCl₄), hexachlorodisilane (Si₂Cl₆), and higher linear, branched or cyclic homologs such as 1,1,2,2-tetrachlorodisilane (Cl₂HSi—SiHCl₂), chlorinated and partially chlorinated oligo- and polysilanes, methylchlorosilanes, such as trichloromethylsilane (MeSiCl₃), dichlorodimethylsilane (MezSiCl₂), chlorotrimethylsilane (Me₃SiCI), tetramethylsilane (Me₄Si), dichloromethylsilane (MeHSiCl₂), chloromethylsilane (MeH₂SiCI), methylsilane (MeH₃Si), chlorodimethylsilane (MezHSiCI), dimethylsilane (MezH₂Si), trimethylsilane (MesSiH) and mixtures of the silicon compounds described.

In particular, the Si precursor is selected from the group comprising monosilane, disilane, trichlorosilane, dichlorosilane, methylsilane and mixtures thereof.

Further reactive constituents that may be present in the reaction gas comprise hydrogen or else hydrocarbons selected from the group comprising aliphatic hydrocarbons having 1 to 10 carbon atoms, preferably 1 to 6 carbon atoms, such as methane, ethane, propane, butane, pentane, isobutane, hexane, cyclopropane, cyclobutane, cyclopentane, cyclohexane, cycloheptane; unsaturated hydrocarbons having 1 to 10 carbon atoms such as ethene, acetylene, propene, methylacetylene butylenes, butynes (1-butyne, 2-butyne) isoprene, butadiene, divinylbenzene, vinylacetylene, cyclohexadiene, cyclooctadiene, cyclic unsaturated hydrocarbons, such as cyclopropene, cyclobutene, cyclopentene, cyclohexene, cyclohexadiene, cyclopentadiene, dicyclopentadiene or norbornadiene, aromatic hydrocarbons, such as benzene, toluene, p-, m-, o-xylene, styrene (vinylbenzene), ethylbenzene, diphenylmethane or naphthalene, other aromatic hydrocarbons, such as phenol, o-, m-, p-cresol, cymene, nitrobenzene, chlorobenzene, pyridine, anthracene and phenanthrene, myrcene, geraniol, thioterpineol, norbornane, borneol, isoborneol, bornane, camphor, limonene, terpinene, pinene, pinane, carene, phenol, aniline, anisole, furan, furfural, furfuryl alcohol, hydroxymethylfurfural, bishydroxymethylfuran and mixed fractions comprising a multiplicity of such compounds, such as from natural gas condensates, petroleum distillates, coke oven condensates, mixed fractions from the product streams of a fluid catalytic cracker (FCC), steam cracker or a Fischer-Tropsch synthesis plant, or more generally hydrocarbon-containing material streams from wood, natural gas, petroleum and coal processing.

The porous particles for the process according to the invention are preferably selected from the group comprising amorphous carbon in the form of hard carbon, soft carbon, mesocarbon, microbeads, natural graphite or synthetic graphite, single- and multi-walled carbon nanotubes and graphene, oxides such as silicon dioxide, aluminum oxide, silicon-aluminum mixed oxides, magnesium oxide, lead oxides and zirconium oxide, carbides such as silicon carbide and boron carbides, nitrides such as silicon nitride and boron nitrides, and other ceramic materials, such as may be described by the following component formula:

AlₐB_{b}C_{c}Mg_{d}NₑO_{f}Si_{g} where 0≤a, b, c, d, e, f, g≤1, with at least two coefficients a to g>0 and a*3+b*3+c*4+d*2+g*4≥e*3+f*2.

The ceramic materials may be, for example, binary, ternary, quaternary, quinary, senary or septernary compounds. Preference is given to ceramic materials having the following component formulae:

non-stoichiometric boron nitrides BN_{z} where z=0.2 to 1, non-stoichiometric carbon nitrides CN_{z} where z=0.1 to 4/3, boron carbonitrides BₓCN_{z} where x=0.1 to 20 and z=0.1 to 20, where x*3+4≥ z*3, boron nitride oxides BN_{z}Oᵣ where z=0.1 to 1 and r=0.1 to 1, where 3≥ r*2+z*3, boron carbonitride oxides BₓCN_{z}Oᵣ where x=0.1 to 2, z=0.1 to 1 and r=0.1 to 1, where: x*3+4≥ r*2+z*3, silicon carbon oxides SiₓCO_{z} where x=0.1 to 2 and z=0.1 to 2, where x*4+4≥ z*2, silicon carbonitrides SiₓCN_{z} where x=0.1 to 3 and z=0.1 to 4, where x*4+4≥ z*3, silicon boron carbonitrides Si_{w}BₓCN_{z} where w=0.1 to 3, x=0.1 to 2 and z=0.1 to 4, where w*4+x*3+4≥ z*3, silicon boron carbon oxides Si_{w}BₓCO_{z} where w=0.10 to 3, x=0.1 to 2 and z=0.1 to 4, where w*4+x*3+4≥ z*2, silicon boron carbonitride oxides SiᵥB_{w}CNₓO_{z} where v=0.1 to 3, w=0.1 to 2, x=0.1 to 4 and z=0.1 to 3, where v*4+w*3+4≥ x*3+z*2 and aluminum boron silicon carbonitride oxides AlᵤBᵥSiₓCN_{w}O_{z} where u=0.1 to 2, v=0.1 to 2, w=0.1 to 4, x=0.1 to 2 and z=0.1 to 3, where u*3+v*3+x*4+4≥w*3+z*2.

The porous particles are preferably amorphous carbon selected from the group comprising hard carbon, soft carbon, mesocarbon, microbeads, natural graphite or synthetic graphite, single- and multi-walled carbon nanotubes, graphene and mixtures thereof.

The porous particles preferably have a density, determined by helium pycnometry, of 0.1 to 7 g/cm³ and particularly preferably of 0.3 to 3 g/cm³. This is advantageous for increasing the volumetric capacity (mAh/cm³) of lithium-ion batteries.

The porous particles have a volume-weighted particle size distribution with diameter percentiles d₅₀ of preferably ≥0.5 μm, particularly preferably ≥1.5 μm and most preferably ≥2 μm. The diameter percentiles d₅₀ are preferably ≤20 μm, more preferably ≤12 μm and most preferably ≤8 μm.

The volume-weighted particle size distribution of the porous particles is preferably between the diameter percentiles d₁₀≥0.2 μm and d₅₀≤20.0 μm, particularly preferably between d₁₀≥0.4 μm and d₉₀≤15.0 μm and most preferably between d₁₀≥ 0.6 μm to d₉₀≤12.0 μm.

The porous particles have a volume-weighted particle size distribution with diameter percentiles d₁₀ of preferably ≤10 μm, particularly preferably ≤5 μm, especially preferably ≤3 μm and most preferably ≤2 μm. The diameter percentiles d₁₀ are preferably ≥0.2 μm, particularly preferably ≥0.5 and most preferably ≥1 μm.

The porous particles have a volume-weighted particle size distribution with diameter percentiles doo of preferably ≥4 μm and particularly preferably ≥8 μm. The diameter percentiles d₅₀ are preferably ≤18 μm, more preferably ≤15 and most preferably ≤13 μm.

The volume-weighted particle size distribution of the porous particles has a width d₉₀-d₁₀ of preferably ≤15.0 μm, more preferably ≤12.0 μm, particularly preferably ≤10.0 μm, especially preferably ≤8.0 μm and most preferably ≤4.0 μm.

The volume-weighted particle size distribution of the Si composite producible by the process according to the invention has a width d₉₀-d₁₀ of preferably ≥0.6 μm, particularly preferably ≥0.8 μm and most preferably ≥1.0 μm.

The volume-weighted particle size distribution of the porous particles is determinable according to ISO 13320 by static laser scattering using the Mie model with the Horiba LA 950 measuring device with ethanol as the dispersing medium for the porous particles.

The porous particles are preferably in the form of individual particles. The particles can be isolated or agglomerated for example. The porous particles are preferably non-aggregated and preferably non-agglomerated. Aggregated generally means that in the course of the production of the porous particles, primary particles are initially formed and grow together and/or primary particles are linked to one another, for example via covalent bonds, and in this way form aggregates. Primary particles are generally isolated particles. Aggregates or isolated particles can form agglomerates. Agglomerates are a loose accumulation of aggregates or primary particles that are linked to one another, for example, via van der Waals interactions or hydrogen bonds. Agglomerated aggregates can easily be split back into aggregates again by common kneading and dispersing processes. Aggregates can be broken down into the primary particles only partially by such processes, if at all. The presence of porous particles in the form of aggregates, agglomerates or isolated particles can be visualized for example using conventional scanning electron microscopy (SEM). By contrast, static light scattering methods for determining particle size distributions or particle diameters of matrix particles cannot distinguish aggregates and agglomerates.

The porous particles may have any morphology, i.e. for example, be splintered, flaky, spherical or else needle-shaped, with splintered or spherical particles being preferred. The morphology may, for example, be characterized by the sphericity Ψ or the sphericity S. According to Wadell's definition, the sphericity Ψ is the ratio of the surface area of a sphere of equal volume to the actual surface area of a body. In the case of a sphere, Ψ is 1. According to this definition the porous particles for the process according to the invention have a sphericity Ψ of preferably 0.3 to 1.0, particularly preferably of 0.5 to 1.0 and most preferably of 0.65 to 1.0.

The sphericity S is the ratio of the circumference of an equivalent circle with the same area A as the projection of the particle projected onto a surface and the measured circumference U of this projection: S=2πA/U. In the case of an ideal circular particle, S would have the value 1. For the porous particles for the process according to the invention the sphericity S is preferably 0.5 to 1.0 and particularly preferably in the range from 0.65 to 1.0, based on the percentiles S₁₀ to S₉₀ of the sphericity number distribution. The measurement of sphericity S is carried out for example with reference to micrographs of individual particles with an optical microscope or, in the case of particles<10 μm, preferably with a scanning electron microscope by graphical evaluation using image analysis software such as ImageJ.

The porous particles preferably have a gas-accessible pore volume of ≥0.2 cm³/g, particularly preferably ≥0.6 cm³/g and most preferably ≥1.0 cm³/g. This is advantageous for obtaining high-capacity LIB. The gas-accessible pore volume was determined by gas sorption measurements with nitrogen according to DIN 66134.

The porous particles are preferably open-pored. Open-pored generally means that pores are connected to the surface of particles, for example via channels, and can preferably exchange mass with the environment, in particular exchange gaseous compounds. This can be demonstrated by gas sorption measurements (analysis according to Brunauer, Emmett and Teller, “BET”), i.e. the specific surface area. The porous particles have specific surface areas of preferably ≥50 m²/g, particularly preferably ≥500 m²/g and most preferably ≥1000 m²/g. The BET surface area is determined according to DIN 66131 (with nitrogen).

The pores of the porous particles may have any diameter, i.e. generally in the range of macropores (above 50 nm), mesopores (2-50 nm) and micropores (smaller than 2 nm). The porous particles may be used in any mixtures of different pore types. Preference is given to using porous particles having less than 30% macropores, based on the total pore volume, particularly preferably porous particles without macropores and very particularly preferably porous particles having at least 50% pores having an average pore diameter of less than 5 nm. It is very particularly preferable when the porous particles have exclusively pores having a pore diameter of less than 2 nm (method of determination: pore size distribution according to BJH (gas adsorption) in accordance with DIN 66134 in the mesopore range and according to Horvath-Kawazoe (gas adsorption) in accordance with DIN 66135 in the micropore range; the pore size distribution in the macropore range is evaluated by mercury porosimetry according to DIN ISO 15901-1).

Preference is given to porous particles having gas-inaccessible pore volumes of less than 0.3 cm³/g and particularly preferably less than 0.15 cm³/g. This too can be used to increase the capacity of the LIBs. The gas-inaccessible pore volume can be determined using the following formula:

$$Gas - inaccessible pore volume = 1 / pure - material density - 1 / skeletal density .$$

The pure-material density is a theoretical density of the porous particles, based on the phase composition or the density of the pure substance (density of the material as if it had no closed porosity). Pure-material density data can be found by a person skilled in the art, for example, in the Ceramic Data Portal of the National Institute of Standards (NIST, https://srdata.nist.gov/CeramicDataPortal/scd). For example the pure-material density of silicon oxide is 2.203 g/cm³, that of boron nitride is 2.25 g cm³, that of silicon nitride is 3.44 g/cm³ and that of silicon carbide is 3.21 g/cm³. The skeletal density is the actual density of the porous particles (gas-accessible) as determined by helium pycnometry.

The porous particles generally function as starting material for producing the silicon composite. It is preferable when there is no silicon, i.e. in particular no silicon obtained by deposition of Si precursors, in the pores of the porous particles and on the surface of the porous particles.

The silicon composite obtainable by the process according to the invention by deposition of silicon in pores and on the surface of the porous particles may have a volume-weighted particle size distribution with diameter percentiles d₅₀ in a range from 0.5 to 20 μm. The d₅₀ value is preferably at least 1.5 μm, and particularly preferably at least 2 μm. The diameter percentiles d₅₀ are preferably at most 13 μm and particularly preferably at most 8 μm.

The volume-weighted particle size distribution of the silicon composite is preferably between the diameter percentiles d_{10≥0.2} μm and d_{90≤20.0} μm, particularly preferably between d_{10≥0.4} μm and d_{90≤15.0} μm and in particular between d_{10≥0.6} μm to d_{90≤12.0} μm.

The silicon composite has a volume-weighted particle size distribution with diameter percentiles d₁₀ of preferably ≤10 μm, particularly preferably ≤5 μm, especially preferably ≤3 μm and most preferably ≤1 μm. The diameter percentiles d₁₀ are preferably ≥0.2 μm, particularly preferably ≥0.4 μm and in particular ≥0.6 μm.

The silicon composite material has a volume-weighted particle size distribution with diameter percentiles do of preferably ≥5 μm and particularly preferably ≥10 μm. The diameter percentiles d₉₀ are preferably ≤20 μm, particularly preferably ≤15 μm and in particular ≤12 μm.

The volume-weighted particle size distribution of the silicon composite may have a width d₉₀-d₁₀ of ≤15.0 μm, preferably ≤12.0 μm, particularly preferably ≤10.0 μm, in particular ≤8.0 μm and especially preferably of ≤4.0 μm. The volume-weighted particle size distribution of the silicon has a width d₉₀-d₁₀ of preferably ≥0.6 μm, particularly preferably ≥0.8 μm and in particular ≥1.0 μm.

The particles of the silicon composite are preferably in the form of particles. The particles can be isolated or agglomerated. The silicon composite is preferably non-aggregated and preferably non-agglomerated. The terms isolated, agglomerated and non-aggregated have already been defined above in respect of the porous particles. The presence of silicon composite in the form of aggregates or agglomerates can be visualized for example using conventional scanning electron microscopy (SEM).

The Si composite may have any morphology, i.e. for example, be splintered, flaky, spherical or else needle-shaped, with splintered or spherical particles being preferred.

According to Wadell's definition, the sphericity Ψ is the ratio of the surface area of a sphere of equal volume to the actual surface area of a body. In the case of a sphere, w is 1. According to this definition the Si composites obtainable by the process according to the invention have a sphericity Ψ of preferably 0.3 to 1.0, particularly preferably of 0.5 to 1.0 and most preferably of 0.65 to 1.0.

The sphericity S is the ratio of the circumference of an equivalent circle with the same area A as the projection of the particle projected onto a surface and the measured circumference U of this projection: S=2πA/U. In the case of an ideal circular particle, S would have the value 1. For the silicon composite obtainable by the process according to the invention the sphericity S is in the range of preferably 0.5 to 1.0 and particularly preferably 0.65 to 1.0, based on the percentiles S₁₀ to S₉₀ of the sphericity number distribution. The measurement of sphericity S is carried out for example with reference to micrographs of individual particles with an optical microscope or, in the case of particles smaller than 10 μm, preferably with a scanning electron microscope (SEM), by graphical evaluation using image analysis software, such as ImageJ.

The cycling stability of LIBs can be further increased via the morphology, the material composition, in particular the specific surface area or the internal porosity of the silicon composite.

If the porous particles comprise Si compounds, for example in the form of silicon dioxide, the above data in % by weight can be determined for the silicon obtained via the deposition from the Si precursor by subtracting the Si mass of the porous particles determined by elemental analysis from the Si mass of the silicon composite determined by elemental analysis and dividing the result by the mass of the silicon composite.

The volume of the silicon deposited in porous particles is derivable from the mass fraction of the silicon obtained by deposition from the Si precursor in the total mass of the silicon composite divided by the density of silicon (2.336 g/cm³).

The pore volume P of the silicon composite is derivable from the sum of gas-accessible and gas-inaccessible pore volumes. The Gurvich gas-accessible pore volume of the silicon composite is determinable by gas sorption measurements with nitrogen according to DIN 66134.

The gas-inaccessible pore volume of the silicon composite is determinable according to: Gas-inaccessible pore volume=1/skeletal density−1/pure material density as described above.

The pore volume P of the Si composite is preferably in the range from 0% to 400% by volume, particularly preferably in the range from 100% to 350% by volume and especially preferably in the range from 200% to 350% by volume, based on the volume of the silicon present in the Si composite and obtained from the deposition of the Si precursor.

The porosity of the silicon composite may be either gas-accessible or gas-inaccessible. The ratio of the volume of gas-accessible to gas-inaccessible porosity of the silicon composite may generally be in the range from 0 (no gas-accessible pores) to 1 (all gas-accessible). The ratio of the volume of gas-accessible to gas-inaccessible porosity of the silicon composite is preferably in the range from 0 to 0.8, particularly preferably in the range from 0 to 0.3 and particularly preferably 0 to 0.1.

The pores of the silicon composite may have any diameters, for example in the range of macropores (>50 nm), mesopores (2-50 nm) and micropores (<2 nm). The Si composite may also comprise any mixtures of different pore types. It preferably comprises a maximum of 30% macropores, based on the total pore volume. Particular preference is given to an Si composite without macropores and very particular preference is given to an Si composite having at least 50% pores, based on the total pore volume, having an average pore diameter below 5 mm. The Si composite especially preferably comprises exclusively pores having a diameter of at most 2 nm.

The Si composite comprises silicon structures which in at least one dimension have structure sizes of preferably at most 1000 nm, particularly preferably less than 100 nm, in particular less than 5 nm (determination method: SEM and/or high-resolution transmission electron microscopy (HR-TEM)).

The Si composite preferably contains Si layers having a layer thickness of less than 1000 nm, particularly preferably less than 100 nm, in particular less than 5 nm (determination: SEM and/or HR-TEM). The Si composite may also contain silicon in the form of particles. Si particles have a diameter of preferably at most 1000 nm, particularly preferably less than 100 nm, in particular less than 5 nm (determination: SEM and/or HR-TEM). The FIGURE for the Si particles preferably relates here to the diameter of the circumference of the particles in the micrograph.

It is preferable when the amount of coarse silicon in the deposited silicon is less than 3% by weight, particularly preferably less than 1% by weight, especially preferably less than 0.1% by weight.

The Si composite preferably has a specific surface area of at most 100 m²/g, particularly preferably less than 30 m²/g and especially preferably less than 10 m²/g. The BET surface area is determined according to DIN 66131 (with nitrogen). This allows SEI formation to be reduced and initial coulombic efficiency to be increased when using the Si composite as active material in anodes for LIBs.

Furthermore, the silicon deposited from the Si precursor in the Si composite may comprise dopants, for example selected from the group comprising Li, Fe, Al, Cu, Ca, K, Na, S, Cl, Zr, Ti, Pt, Ni, Cr, Sn, Mg, Ag, Co, Zn, B, P, Sb, Pb, Ge, Bi, rare earths and combinations thereof. Li and/or Sn are preferred. The content of dopants in the Si composite is preferably at most 1% by weight and particularly preferably at most 100 ppm, based on the total weight of the Si composite, determinable by ICP-OES.

The Si composite has a surprisingly high stability under compressive load and/or shear stress. The compressive load stability and the shear stability is apparent for example from the fact that the Si composite has only slight changes, if any, in its porous structure in the SEM under compressive load (for example during electrode compaction) and under shear stress (for example during electrode preparation).

The Si composite may optionally contain additional elements such as carbon. Carbon is preferably present in the form of thin layers having a layer thickness of at most 1 μm, preferably less than 100 nm, particularly preferably less than 5 nm and especially preferably less than 1 nm (determination: SEM AND HR-TEM). The C layers may be present both in the pores and on the surface of the Si composite. It is also possible to freely choose the sequence of different layers in the Si composite through appropriate repetitions of the alternating metered addition of different precursors, and the numbers thereof. Thus there may firstly be a layer on the porous particles of a further material distinct from the porous particles, such as carbon, and thereupon a Si layer or a layer of Si particles. There may also in turn be a layer, on the Si layer or on the layer of Si particles, of a further material which may be distinct from the material of the porous particles or identical to said material, irrespective of whether a further layer of a material distinct from the material of the porous particles is present between the porous particles and the Si layer or the layer consisting of Si particles.

The Si composite may contain≤50% by weight, preferably ≤40% by weight, particularly preferably ≤20% by weight, of additional elements. The silicon composite may in particular contain ≥1% by weight, especially preferably ≥2% by weight, of additional elements. The FIGURES in % by weight refer to the total weight of the Si composite. It is also possible for the Si composite to contain no additional elements.

The Si composite obtained by the process according to the invention is suitable as active material in anode materials for anodes of LIBs and the use of such anodes is suitable for production of LIBs. All substances and materials required for production are generally known. Production of the components of such batteries and the assembly thereof is carried out by processes familiar in the field of battery production.

The Si composite obtained by the processes according to the invention is characterized by markedly improved electrochemical behavior and results in LIBs having high volumetric capacities and excellent performance characteristics. The Si composite is permeable to Li ions and electrons, thus enabling charge transport. TheSEls in LIBs can be reduced to a large extent with the Si composite obtained. In addition, due to to the design of the Si composite, the SEI becomes detached from the surface of the active material at least to a much lesser extent, if at all. All this leads to a high cycling stability of LIBs, the anodes of which contain the Si composite obtainable by the process according to the invention.

The following examples serve to further elucidate the invention described here.

The following analytical methods and instruments were used for characterization:

### Inorganic Analysis/Elemental Analysis:

The carbon contents reported in the examples were determined with a Leco CS 230 analyzer; for determination of O and optionally N or H contents a Leco TCH-600 analyzer was used. Qualitative and quantitative determination of other specified elements was carried out by ICP (inductively-coupled plasma) emission spectrometry (Optima 7300 DV, Perkin Elmer). To this end the samples were subjected to acid digestion (HF/HNO₃) in a microwave (Microwave 3000, from Anton Paar). The ICP-OES determination is based on ISO 11885 “Water quality— Determination of selected elements by inductively-coupled plasma optical emission spectrometry (ICP-OES) (ISO 11885:2007); German version of EN ISO 11885:2009”, which is used for analysis of acidic aqueous solutions (for example acidified drinking water, wastewater, and other water samples and aqua regia extracts of soils and sediments). The Si determination method used is generally accurate to ±1% by weight.

### Particle Size Determination:

The particle size distribution was determined in accordance with ISO 13320 by static laser scattering using a Horiba LA 950. In the preparation of the samples, particular care must be taken in dispersing the particles in the measurement solution in order to ensure that what is measured is the size of individual particles and not that of agglomerates. The particles were dispersed in ethanol for measurement. Prior to measurement, the dispersion was if necessary sonicated for 4 min at 250 W in a Hielscher UIS250v laboratory ultrasound device with LS24d5 sonotrode.

### BET Surface Area Measurement:

The specific surface area of the materials was measured via gas adsorption with nitrogen using a Sorptomatic 199090 instrument (Porotec) or SA-9603MP instrument (Horiba) by the BET method (determination in accordance with DIN ISO 9277:2003-05 using nitrogen).

### Skeletal Density:

The skeletal density, i.e. the density of the porous solid based on the volume of only the externally gas-accessible pore spaces, was determined by He pycnometry according to DIN 66137-2.

### Gas-Accessible Pore Volume:

The Gurvich gas-accessible pore volume was determined by gas sorption measurements with nitrogen according to DIN 66134.

Thermogravimetry (TGA) and determination of coarse silicon: The reactivity of the powders to oxygen was determined by TGA measurements in pure oxygen in a temperature window of 25-1000° C. using a heating rate of 5 K/min.

### Conversion:

Conversion is calculated as the quotient of the amount of substance in mol of the converted starting material based on the amount of substance in mol of the employed starting material (reactant). Conversion indicates how many of the employed SiH₄ molecules are converted into Si at a particular time. Conversion is variable and may change over the process duration.

$${SiH}_{4} conversion in \% \frac{Amount of substance of Si recovered}{Amount of substance of {SiH}_{4} used} * 100 \%$$

Overall conversion indicates how much silicon has been deposited relative to the metered-in silicon over the entire process.

### Throughput:

Throughput describes how many % by weight of Si are metered in over one hour. It is calculated from the Si content (target content of Si) of the withdrawn product in % by weight relative to the deposition time over all phases in hours.

$$Throughput , in \% by wt . / h = \frac{Total of amount of Si deposited in \% by wt .}{Total duration of metering of Si precursor in h}$$

### EXAMPLES

The examples sought to produce a Si composite having a silicon proportion of 47% to 49% by weight.

The employed SiH₄, quality 4.0, was obtained from Linde GmbH.

In all examples the amorphous carbon was employed as porous starting material:

$$spec . surface area = 1636 {m}^{2} / g$$

$$pore volume = 0.76 {cm}^{2} / g$$

$$average volume - weighted particle size D50 = 6.4 μ m$$

### Proportion of Deposited Silicon Based on Target Content:

0.1% to 50% of the target content are to be deposited during stage A or altogether at most 50% of the target content are to be deposited during two or more stages A.

This proportion of deposited Si during one stage A or during regular operation based on the target content indicates the relative proportion of Si deposited in the corresponding phase. For example a 48% by weight target content of Si for a composite corresponds to a relative proportion of deposited Si of 100%. 50% of Si deposited during stage A then corresponds to a target content of Si of 24% by weight in the composite.

Determination of fine and coarse silicon in a sample can be performed using TGA measurements via the reaction of silicon with oxygen to form SiO₂. The distinguishability of different Si species may be due to the fact that thin silicon layers have a higher reactivity towards oxygen than thick layers or Si particles. This has the result that in TGA measurements thin Si layers react (increase in mass) even at low temperatures (400-655° C.) and thick layers/coarse Si structures show a reaction only at temperatures of more than 700° C. Ideally, silicon-containing composites that are to be used as anode active materials show no increase in mass in a TGA measurement under oxygen-containing atmosphere at temperatures of more than 800° C. This method further allows determination of the content of elemental silicon. Silicon previously oxidized and passivated by contact with air no longer takes part in the reaction and is thus not taken into account in the TGA measurements.

Calculating the coarse silicon present requires the residual mass (mred) from the TGA method and the mass difference (mdiff) which results from oxidation of the coarse silicon. Using the molar mass of O₂ (32 g/mol) and the molar mass of SiO₂ (60.08 g/mol) the proportion of coarse silicon in the deposited silicon can now be calculated using the following formula:

$$Coarse Si = mdiff * \frac{60.08 \frac{g}{mol}}{32 \frac{g}{mol} * mred} * 100 \%$$

### Comparative Example 1: Production of an Si Composite in a Reactor Suitable Therefor

A tubular reactor was charged with 2.2 g of the porous carbon particles (spec. surface area=1636 m²/g; Gurvich pore volume=0.76 cm³/g, average volume-weighted particle size D₅₀=6.40 μm) in a quartz glass boat. After inertization with nitrogen, the reactor was heated to 410° C. Upon reaching this temperature the Si precursor (50% SiH₄ in N₂, 10 NL/h) was passed into the reactor. The decomposition reaction of the SiH₄ to afford Si was monitored and quantified via a thermal conductivity detector in the offgas stream. After 2.1 g of Si had been deposited the SiH₄ gas stream was switched to a pure nitrogen stream and the heating was turned off. The reactor was cooled to room temperature with N₂ purging and the product was withdrawn.

### Comparative Example 2: Production of a Silicon Composite in a Reactor Suitable Therefor

A tubular reactor was charged with 2.2 g of the porous carbon particles (spec. surface area=1636 m²/g, Gurvich pore volume=0.76 cm³/g, average volume-weighted particle size D₅₀=6.40 μm) in a quartz glass boat. After inertization with nitrogen, the reactor was heated to 380° C. Upon reaching this temperature the Si precursor (50% SiH₄ in N₂, 10 NL/h) was passed into the reactor. The decomposition reaction of the SiH₄ to afford Si was monitored and quantified via a thermal conductivity detector in the offgas stream. After 2.1 g of Si had been deposited the SiH₄ gas stream was switched to a pure nitrogen stream and the heating was turned off. The reactor was cooled to room temperature with N₂ purging and the product was withdrawn.

### Examples 1-2: Production of an Si Composite by a Process According to the Invention Having a Stage a (the Index a Indicates the Parameters of Stage A)

A tubular reactor was charged with 2.2 g of the porous carbon particles (spec. surface area=1636 m²/g, Gurvich pore volume=0.76 cm³/g, average volume-weighted particle size D₅₀=6.40 μm) in a quartz glass boat. After inertization with nitrogen the reactor was heated to T_{A} (stage (index) A). Upon reaching the target temperature the monosilane was passed into the reactor as a mixture with N₂ (concentration C_{A}, volume flow of Si precursor VS_{A}). The decomposition reaction of the SiH₄ to afford Si was monitored and quantified via a thermal conductivity detector in the offgas stream. Once MA [g] of Si had been deposited the plant was switched to regular operation (index R): temperature T_{R}, monosilane concentration C_{R}. volume flow rate of Si precursor VS_{R}, and the further Si amount M_{R} was deposited in regular operation. The reactor was then cooled to room temperature with N₂ purging and the silicon composite was withdrawn.

TABLE 1
Experimental parameters for inventive examples 1 to 2

| | | Example number | |
|---|---|---|---|
| Experimental parameters | Description | Ex 1 | Ex 2 |
| Si deposited in regular operation, [g] | M_{R} | 2.220 | 1.910 |
| Si deposited in stage A, [g] | M_{A} | 0.006 | 0.004 |
| Temperature in regular operation, [° C.] | T_{R} | 410 | 400 |
| Temperature in stage A, [° C.] | T_{A} | 380 | 400 |
| SiH₄ conc in regular | C_{R} | 50 | 50 |
| operation, [% by vol.] | | | |
| SiH₄ conc in stage A, [% by vol.] | C_{A} | 50 | 30 |
| Volume flow of SiH₄ per gram | VS_{R} | 2.27 | 2.27 |
| of carbon in regular operation [NL/h per | | | |
| gram of carbon in reactor] | | | |
| Volume flow of SiH₄ per | VS_{A} | 2.27 | 1.36 |
| gram of carbon in stage A [NL/h | | | |
| per gram of carbon in reactor] | | | |

### Examples 3-4: Production of Si Composite by the Process According to the Invention with Two or More Stages a

A tubular reactor was charged with 2.2 g of the porous carbon particles (spec. surface area=1636 m²/g, Gurvich pore volume=0.76 cm³/g, average volume-weighted particle size D₅₀=6.40 μm) in a quartz glass boat. After inertization with nitrogen the reactor was heated to T_{A1} (stage (index) A1). Upon reaching the target temperature the monosilane was passed into the reactor as a mixture with N₂ (concentration C_{A1}, volume flow of Si precursor VS_{A1}). The decomposition reaction of the SiH₄ to afford Si was monitored and quantified via a thermal conductivity detector in the offgas stream. Once M_{A1} [g] of Si had been deposited (stage (index) A1) the plant was switched to regular operation: temperature T_{R}, monosilane concentration C_{R}, volume flow rate of Si precursor VS_{R}, and the further Si amount M_{R} [g] was deposited in regular operation. Once M_{R} [g] silicon had been deposited in regular operation (target content of Si up to that moment M_{A1}+M_{R}) the plant was switched again and a new change Δ was undertaken (stage (index) A2): temperature T_{A}2, monosilane concentration C_{A2}. volume flow of Si precursor VS_{A2}, and the further Si amount M_{A2} [g] was deposited. The reactor was then purged with N₂ and cooled to room temperature and the product was withdrawn.

TABLE 2
Experimental parameters for inventive examples 1 to 2

| | | Example number | |
|---|---|---|---|
| Experimental parameters | Description | Ex 3 | Ex 4 |
| Si deposited in regular operation, [g] | M_{R} | 1.58 | 1.24 |
| Si deposited in stage A1, [g] | M_{A1} | 0.20 | 0.42 |
| Si deposited in stage A2, [g] | M_{A2} | 0.20 | 0.42 |
| Temperature in regular operation, [° C.] | T_{R} | 410 | 400 |
| Temperature in stage A1, [° C.] | T_{A1} | 380 | 400 |
| Temperature in stage A2, [° C.] | T_{A2} | 380 | 400 |
| SiH₄ conc in regular | C_{R} | 50 | 100 |
| operation, [% by vol.] | | | |
| SiH₄ conc in stage A1, [% by vol.] | C_{A1} | 50 | 50 |
| SiH₄ conc in stage A2, [% by vol.] | C_{A2} | 50 | 50 |
| Volume flow of SiH₄ in | VS_{R} | 2.27 | 4.55 |
| regular operation, [NL/h | | | |
| per gram of carbon in reactor] | | | |
| Volume flow of SiH₄ in | VS_{A1} | 2.27 | 2.27 |
| stage A1, [NL/h per | | | |
| gram of carbon in reactor] | | | |
| Volume flow of SiH₄ in | VS_{A2} | 2.27 | 2.27 |
| stage A2, [NL/h per | | | |
| gram of carbon in reactor] | | | |

The reaction conditions for production and the material properties of the Si composite are summarized in the following table 3.

TABLE 3

| | Comp | Comp ex | | | | |
|---|---|---|---|---|---|---|
| | ex 1* | 2* | Ex 1 | Ex 2 | Ex 3 | Ex 4 |
| Regular operation: Proportion of target content in | 100 | 100 | 99.72 | 99.8 | 80 | 60 |
| product, [% Si] | | | | | | |
| Regular operation: Temperature T_{R}, [° C.] | 410 | 380 | 410 | 400 | 410 | 400 |
| Regular operation: Monosilane conc. C_{R}, [% by vol.] | 50 | 50 | 50 | 50 | 50 | 100 |
| Regular operation: Monosilane volume flow VS_{R} | 2.27 | 2.27 | 2.27 | 2.27 | 2.27 | 4.55 |
| [NL/h per gram of carbon in reactor] | | | | | | |
| Stage A: Proportion of target content in product, [% Si] | — | — | 0.27 | 0.21 | 20 | 40 |
| Stage A: Temperature T_{A}, [° C.] | — | — | 380 | 400 | 380 | 400 |
| Stage A: Monosilane conc. C_{A}, [% by vol.] | — | — | 50 | 30 | 50 | 50 |
| Stage A: Monosilane volume flow VS_{A} [NL/h per gram | — | — | 2.27 | 1.36 | 2.27 | 2.27 |
| of carbon in reactor] | | | | | | |
| ΔT, [° C.] | — | — | 20 | 0 | 30 | 0 |
| ΔC, [% by vol.] | — | — | 0 | 20 | 0 | 50 |
| ΔVS, [NL/h per gram of carbon in reactor] | — | — | 0 | 0.90 | 0 | 0 |
| Overall conversion, [%] | 56.84 | 19.42 | 53.55 | 44.97 | 50.21 | 64.31 |
| Throughput [% by wt./h] | 82.76 | 28.74 | 49.48 | 63.16 | 45.49 | 75.68 |
| Amount of reactant, [g] | 2.20 | 2.20 | 2.20 | 2.20 | 2.20 | 2.20 |
| Amount of product, [g] | 4.29 | 4.22 | 4.22 | 4.11 | 4.18 | 4.28 |
| Si, [% by wt.] | 48 | 48 | 48 | 48 | 48 | 48 |
| O, [% by wt.] | 2.18 | 3.31 | 2.99 | 2.24 | 3.30 | 3.38 |
| Coarse Si, [%] | 0.6 | 0.0 | 0.0 | 0.0 | 0.0 | 0.0 |
| BET, [m²/g] | 9.43 | 30.21 | 12.4 | 11.44 | 26.11 | 17.40 |

*noninventive

According to the selected parameters M_{R}, M_{A}, T_{R}, T_{A}, C_{R}, C_{A}, VS_{A}, and VS_{R}, the overall conversion of the Si precursor and the throughput of the plant can be markedly increased while maximizing material performance.

Evaluation of the Si composite particles in electrochemical cells Example 5: The Si composites from inventive examples 1-4 and from the comparative examples were tested as constituents of anodes in LIBs.

29.71 g of polyacrylic acid (dried at 85° C. to constant weight; Sigma-Aldrich, Mw˜450 000 g/mol) and 756.60 g of deionized water were agitated by means of a shaker (290 1/min) for 2.5 h until dissolution of the polyacrylic acid was complete. Lithium hydroxide monohydrate (Sigma-Aldrich) was added to the solution a little at a time until the pH was 7.0 (measured using WTW pH 340i PH meter and SenTix RJD probe). The solution was then mixed by means of a shaker for a further 4 h. 3.87 g of the neutralized polyacrylic acid solution and 0.96 g of graphite (Imerys, KS6L C) were initially charged in a 50 ml vessel and mixed in a planetary mixer (SpeedMixer, DAC 150 SP) at 2000 rpm. In each case 3.35 g of the silicon composite from examples 1 to 5 and comparative examples 1 and were then stirred in for 1 min at 2000 rpm. 1.21 g of an 8% conductive carbon black dispersion and 0.8 g of deionized water were then added and incorporated in a planetary mixer at 2000 rpm. Dispersion was then carried out in the dissolver for 30 min at 3000 rpm at a constant 20° C. Degassing of the ink was again carried out in the planetary mixer at 2500 rpm for 5 minutes under vacuum. The finished dispersion was then applied to a copper foil having a thickness of 0.03 mm (Schlenk Metallfolien, SE-Cu58) using a film-drawing frame with a gap clearance of 0.06 mm (Erichsen, model 360). The anode coating thus produced was then dried at 50° C. and 1 bar air pressure for 60 min. The average basis weight of the dry anode coating was 2.7 mg/cm² and the coating density 0.8 g/cm³.

The electrochemical studies were carried out using a button cell (CR2032 type, Hohsen Corp.) in a 2-electrode arrangement. The electrode coating was used as the counter electrode or negative electrode (Dm=15 mm). A coating based on lithium-nickel-manganese-cobalt oxide 6:2:2 having a content of 94.0% and an average basis weight of 15.9 mg/cm² (obtained from SEI) was used as the working electrode/positive electrode (Dm=15 mm). A glass fiber filter paper (Whatman, GD Type D) saturated with 60 μl of electrolyte was used as the separator (Dm=16 mm). The electrolyte used consisted of a 1.0 molar solution of lithium hexafluorophosphate in a 1:4 (v/v) mixture of fluoroethylene carbonate and diethyl carbonate. The cell was assembled in a glovebox (<1 ppm H₂O, O₂); the water content in the dry matter of all components used was below 20 ppm.

The electrochemical testing was carried out at 20° C. The cells were charged by the cc/cv method (constant current/constant voltage) with a constant current of 5 mA/g (corresponding to C/25) in the first cycle and of 60 mA/g (corresponding to C/2) in the subsequent cycles and, on attainment of the voltage limit of 4.2 V, at constant voltage until the current went below 1.2 mA/g (corresponding to C/100) or 15 mA/g (corresponding to C/8). The cell was discharged by the cc method (constant current) with a constant current of 5 mA/g (corresponding to C/25) in the first cycle and of 60 mA/g (corresponding to C/2) in the subsequent cycles until attainment of the voltage limit of 2.5 V. The specific current chosen was based on the weight of the coating of the positive electrode. The electrodes were selected such that a cathode:anode capacitance ratio of 1:1.2 was established.

The results of the electrochemical testing of the full cells of LIB containing Si composites from examples 1 to 4 and comparative examples 1 and 2 are shown in table 4.

TABLE 4

| | Reversible specific | Number of cycles | Coulombic |
|---|---|---|---|
| | capacity of negative | with ≥80% | efficiency of |
| Example | electrode in second | capacity | formation [%] |
| no. | cycle, [mAh/g] | retention | [%] |
| Comp ex 1* | 1034 | 391 | 86.5 |
| Comp ex 2* | 1064 | 842 | 85.6 |
| Ex 1 | 1086 | 833 | 85.3 |
| Ex 2 | 1066 | 870 | 86.7 |
| Ex 3 | 1063 | 862 | 85.7 |
| Ex 4 | 1039 | 687 | 85.8 |

*noninventive

Comparative example 1 shows a high throughput coupled with good conversion of the Si precursor but provides a content of coarse Si of 0.6% (table 3) and thus achieves only a low cycling stability. Comparative example 2 shows good electrochemical performance but this was only achievable at low conversion and throughput (table 4).

Inventive examples 1-3 show a higher throughput and higher conversion relative to comparative example 2 while maintaining very good electrochemical performance. In contrast to comparative example 1, examples 1-3 provide no coarse Si and are therefore to be regarded as advantageous. By adapting temperature and silane concentration example 4 achieves better electrochemical performance than comparative example 1 with simultaneously higher conversion.

1.-16. (canceled)

17. A process for producing a silicon composite, comprising:
wherein the silicon composite is produced by thermal decomposition of at least one Si precursor in the presence of porous particles;
wherein silicon is deposited in pores and on the surface of the porous particles and the silicon composite has a target content of Si of 35% to 60% by weight;
wherein in operation the process is performed at an average temperature T of 300° C. to 500° C. and a concentration C of the at least one Si precursor of 30% to 100% by volume;
wherein the process comprises at least one stage A in which a change 4 in at least one of the parameters T and C relative to regular operation and optionally relative to a further stage A is effected;
wherein ΔT=10° C. to 130° C.;
wherein ΔC=2% to 70% by volume; and
wherein during the at least one stage A 0.1% to 50% of the recited target content is deposited or that during two or more of the at least one stage A altogether at most 50% of the recited target content is deposited.

18. The process of claim 17, wherein the silicon composite has a target content of Si of 40% to 55% by weight, preferably of 42% to 50% by weight.

19. The process of claim 17, wherein the target content of Si is determined during the process by analysis of the composition of an offgas stream with at least one method selected from the group comprising gas chromatography, mass spectrometry, infrared spectroscopy and thermal conductivity measurement.

20. The process of claim 17, wherein Tis 315° C. to 475° C., preferably 330° C. to 450° C.

21. The process of claim 17, wherein C is 40% to 100% by volume, preferably 50% to 100% by volume.

22. The process of claim 17, wherein the ΔT is 20° C. to 100° C., preferably 20° C. to 50° C.

23. The process of claim 17, wherein the ΔC is 5% to 60% by volume, preferably 10% to 50% by volume.

24. The process of claim 17, wherein the change Δ is carried out continuously from commencement of the at least one stage A until termination thereof.

25. The process of claim 17, wherein the process is performed at a pressure of less than 0.7 MPa.

26. The process of claim 17, wherein the process is performed in a reactor fitted with a close-clearance stirrer; and/or
wherein the process is performed in a cascade reactor system comprising two or more reactors.

27. The process of claim 17, wherein the at least one Si precursor is selected from the group comprising monosilane, disilane, trichlorosilane, dichlorosilane, methylsilane and mixtures thereof; and/or
wherein the porous particles are amorphous carbon selected from the group comprising hard carbon, soft carbon, mesocarbon, microbeads, natural graphite or synthetic graphite, single- and multi-walled carbon nanotubes, graphene and mixtures thereof.

28. A process for producing a silicon composite, comprising:
wherein the silicon composite is produced by thermal decomposition of at least one silicon precursor in the presence of porous particles;
wherein silicon is deposited in pores and on the surface of the porous particles and the silicon composite has a target content of Si of 35% to 60% by weight;
wherein in operation the process is performed at an average temperature T of 300° C. to 500° C., a concentration C of the silicon precursor of 30% to 100% by volume and at a volume flow VS of the silicon precursor of 0.01 to 20 NL/h, based on 1 g of the porous particles;
wherein the process comprises at least one stage A in which a change 4 in at least one of the parameters T, C and VS relative to regular operation and/or relative to a further stage A is effected;
wherein ΔT=10° C. to 130° C.;
wherein ΔC=2% to 70% by volume;
wherein ΔVS=0.01 to 10 NL/h and
wherein during the at least one stage A 0.1% to 50% of the recited target content is deposited or that during two or more stages A altogether at most 50% of the recited target content is deposited.

29. The process of claim 28, wherein in operation VS is 0.01 to 10 NL/h, particularly preferably 0.01 to 5 NL/h, based on 1 g of the porous particles.

30. The process of claim 28, wherein ΔVS is 0.01 to 5 NL/h, preferably 0.01 to 2 NL/h, based on 1 g of the porous particles.

31. The process of claim 28, wherein the silicon composite has a target content of Si of 40% to 55% by weight, preferably of 42% to 50% by weight.

32. The process of claim 28, wherein the target content of Si is determined during the process by analysis of the composition of an offgas stream with at least one method selected from the group comprising gas chromatography, mass spectrometry, infrared spectroscopy and thermal conductivity measurement.

33. The process of claim 28, wherein Tis 315° C. to 475° C., preferably 330° C. to 450° C.; and/or
wherein C is 40% to 100% by volume, preferably 50% to 100% by volume; and/or
wherein the ΔT is 20° C. to 100° C., preferably 20° C. to 50° C.; and/or
wherein the ΔC is 5% to 60% by volume, preferably 10% to 50% by volume; and/or
wherein the change Δ is carried out continuously from commencement of the at least one stage A until termination thereof.

34. The process of claim 28, wherein the process is performed at a pressure of less than 0.7 MPa.

35. The process of claim 28, wherein the process is performed in a reactor fitted with a close-clearance stirrer; and/or
wherein the process is performed in a cascade reactor system comprising two or more reactors.

36. The process of claim 28, wherein the at least one silicon precursor is selected from the group comprising monosilane, disilane, trichlorosilane, dichlorosilane, methylsilane and mixtures thereof; and/or
wherein the porous particles are amorphous carbon selected from the group comprising hard carbon, soft carbon, mesocarbon, microbeads, natural graphite or synthetic graphite, single- and multi-walled carbon nanotubes, graphene and mixtures thereof.
